(19) United States
(12) Patent Application Publication
(10) Pub. No.: US 2025/0060680 A1
(43) Pub. Date: Feb. 20, 2025

(54) GENERATING AN ALIGNMENT SIGNAL WITHOUT DEDICATED ALIGNMENT STRUCTURES

(71) Applicant: ASML NETHERLANDS B.V., Veldhoven (NL)

(72) Inventors: Aabid PATEL, Stamford, CT (US); Joshua ADAMS, Wilton, CT (US); Lisa DIXON, Bethel, CT (US); Igor Matheus Petronella AARTS, Port Chester, NY (US)

(73) Assignee: ASML NETHERLANDS B.V., Veldhoven (NL)

(21) Appl. No.: 18/721,405

(22) PCT Filed: Dec. 14, 2022
(86) PCT No.: PCT/EP2022/085770

§ 371 Date: Jun. 18, 2024

Related U.S. Application Data
(60) Provisional application No. 63/293,504, filed on Dec. 23, 2021.

(51) Int. Cl. G03F 7/00; G01B 11/27

(52) U.S. Cl. CPC G03F 7/706845; G01B 11/27; G03F 7/70633; G03F 7/70655; G03F 7/706833

(57) ABSTRACT

Generating an alignment signal for alignment of features in a layer of a substrate as part of a semiconductor manufacturing process is described. The present systems and methods can be faster and/or generate more information than typical methods for generating alignment signals because they utilize one or more existing structures in a patterned semiconductor wafer instead of a dedicated alignment structure. A feature (not a dedicated alignment mark) of the patterned semiconductor wafer is continuously scanned, where the scanning includes: continuously irradiating the feature with radiation; and continuously detecting reflected radiation from the feature. The scanning is performed perpendicular to the feature, along one side of the feature, or along both sides of the feature.

### CROSS-REFERENCE TO RELATED APPLICATIONS

This application claims priority of U.S. Provisional Patent Application No. 63/293,504, which was filed on Dec. 23, 2021, and which is incorporated herein in its entirety by reference.

### TECHNICAL FIELD

This description relates generally to generating an alignment signal without a need for dedicated alignment structures.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, deposition, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, deposition, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, deposition, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet or extreme ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but are not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

Generating an alignment signal for alignment of features in a layer of a substrate (e.g., a semiconductor wafer) as part of a semiconductor manufacturing process is described. The systems and methods described here are faster and generate more information than typical methods for generating alignment signals because they utilize existing structures in a patterned semiconductor wafer instead of dedicated alignment structures. Scanning is performed faster and is configured to generate more information than in typical systems for generating metrology signals because the scanning is performed on an existing feature and continuously samples deformation across a large region of the semiconductor wafer, rather than a series of discrete alignment marks, and because the feature spans an interior of a device die, without causing processing and/or packaging issues.

As described below, a feature (not a dedicated alignment mark) of a patterned semiconductor wafer may be continuously scanned, where the scanning comprises: continuously irradiating the feature with radiation; and continuously detecting reflected radiation from the feature. The scanning is performed perpendicular to the feature, along one side of the feature, or along both sides of the feature. As an example, a scribe line is an existing feature that could be utilized for alignment.

According to an embodiment, a system for generating a metrology signal is provided. The system comprises a source configured to irradiate a feature in a patterned substrate with radiation. The feature is different than a dedicated alignment structure. The system comprises a sensor configured to detect reflected radiation from the feature. The system comprises one or more processors configured to generate the metrology signal based on the detected reflected radiation from the feature. The metrology signal comprises measurement information pertaining to the feature.

In some embodiments, the feature comprises one or more structures in the patterned substrate capable of providing a diffraction signal.

In some embodiments, the feature is different than the dedicated alignment structure and other structures that lie near the feature and within an illumination spot.

In some embodiments, the irradiating and the detecting comprises scanning, and the scanning is continuous.

In some embodiments, the feature is a structure capable of generating wide angle diffraction, and the scanning is performed: perpendicular to the feature; along one side of the feature, where a spot size of the radiation is configured to cover the one side of the line and/or edge feature; or along both sides of the feature, where the spot size of the radiation is configured to cover both sides of the feature at the same time.

In some embodiments, the feature comprises a line, an edge, or a fine-pitched series of lines and/or edges; and the feature has a length spanning a region of measurement interest.

In some embodiments, a fine-pitch has a pitch dimension of less than 1 micrometer.

In some embodiments, the irradiating and the detecting comprises scanning, and the scanning is performed faster and is configured to generate more information than in typical systems for generating metrology signals because the scanning is performed on the feature and continuously samples deformation across a large region of a field or wafer rather than a series of discrete alignment marks, and because the feature is configured to span an interior of device dies without causing processing and packaging issues.

In some embodiments, the irradiating and the detecting comprises scanning, and the scanning is performed faster and is configured to generate more information than in typical systems for generating metrology signals because the scanning is performed on the feature in the patterned substrate instead of on the dedicated alignment structure.

In some embodiments, the irradiating and the detecting comprises scanning, and the metrology signal is calibrated based on a scan of the feature isolated from other surrounding structures.

In some embodiments, the irradiating and the detecting comprises scanning, and the metrology signal is calibrated based on a perpendicular or parallel line scan.

In some embodiments, the metrology signal comprises a signal from a parallel flank scan. A signal from a flank scan comprises diffraction oriented perpendicular from a scan direction. The signal from the parallel flank scan comprises a difference between a signal from a first scan of the feature and a second parallel scan of the feature.

In some embodiments, the metrology signal comprises a signal from two parallel flank scans on two corresponding features from two different regions. The signal from the two parallel flank scans comprises a difference between a first signal from a first parallel flank scan from a first region and a second signal from a second parallel flank scan from a second region. A given signal from a given parallel flank scan comprises a difference between a signal from a first scan of the feature and a second parallel scan of the feature. Different regions comprise different dies on one substrate or the same dies between different substrates.

In some embodiments, the irradiating and detecting comprise scanning, and the scanning is performed at a predefined scan speed for a given sampling rate. The predefined scan speed and/or given sampling rate is determined based on a size of the feature.

In some embodiments, the predefined scan speed and/or given sampling rate are adjustable based on the size of the feature.

In some embodiments, sizes of features that can be scanned are determined based on a ratio of the predefined scan speed to the given sampling rate.

In some embodiments, the feature comprises a line and/or an edge, the dedicated alignment structure comprises a diffraction grating, and the line and/or edge feature forms a portion of a design layout, separate from the diffraction grating.

In some embodiments, the metrology signal is an alignment signal or an overlay signal.

In some embodiments, the one or more processors are further configured to determine, based on the metrology signal, an alignment inspection location of the feature.

In some embodiments, the feature is included in a layer of the substrate in a semiconductor device structure, and the one or more processors are further configured to adjust a semiconductor device manufacturing process based on the metrology signal.

According to another embodiment, a method for generating a metrology signal is provided. The method comprises: irradiating a feature in a patterned substrate with radiation, the feature being different than a dedicated alignment structure; detecting reflected radiation from the feature; and generating the metrology signal based on the detected reflected radiation from the feature, the metrology signal comprising measurement information pertaining to the feature.

According to another embodiment, there is provided a non-transitory computer readable medium having instructions thereon, the instructions when executed by a computer, causing operations comprising: irradiating a feature in a patterned substrate with radiation, the feature being different than a dedicated alignment structure; detecting reflected radiation from the feature; and generating the metrology signal based on the detected reflected radiation from the feature, the metrology signal comprising measurement information pertaining to the feature.

According to another embodiment, a method for generating an alignment signal for alignment of features in a layer of a substrate as part of a semiconductor manufacturing process is provided. The method is configured to be performed faster and generate more information than typical methods for generating alignment signals because the method is performed on existing structures in a patterned semiconductor wafer instead of on dedicated alignment structures. The method comprises continuously scanning a line and/or edge feature of the patterned semiconductor wafer, the line and/or edge feature being different than a dedicated alignment mark typically included in the patterned semiconductor wafer. The scanning comprises: continuously irradiating the line and/or edge feature with radiation; and continuously detecting reflected radiation from the line and/or edge feature. The scanning is performed: perpendicular to the line and/or edge feature; along one side of the line and/or edge feature; or along both sides of the line and/or edge feature. The method comprises generating the alignment signal based on the detected reflected radiation from the line and/or edge feature; the alignment signal configured to be used to adjust the semiconductor manufacturing process.

### BRIEF DESCRIPTION OF THE DRAWINGS

The above aspects and other aspects and features will become apparent to those ordinarily skilled in the art upon review of the following description of specific embodiments in conjunction with the accompanying figures.

FIG. 1 schematically depicts a lithography apparatus, according to an embodiment.

FIG. 2 schematically depicts an embodiment of a lithographic cell or cluster, according to an embodiment.

FIG. 3 schematically depicts an example inspection system, according to an embodiment.

FIG. 4 schematically depicts an example metrology technique, according to an embodiment.

FIG. 5 illustrates the relationship between a radiation illumination spot of an inspection system and a metrology target, according to an embodiment.

FIG. 6 illustrates a method for generating a metrology signal, according to an embodiment.

FIG. 7 illustrates a first possible version of scanning where a radiation beam trajectory is perpendicular to a feature, according to an embodiment.

FIG. 8 illustrates a second possible version of scanning where the radiation beam trajectory follows one edge of a feature, according to an embodiment.

FIG. 9 illustrates a third possible version of scanning where the radiation beam trajectory follows both edges of a feature, according to an embodiment.

FIG. 10 illustrates an equation that defines a relationship between scan speed, sampling rate, and minimum resolvable feature size, where DF represents the cutoff frequency of the detection system electronics, according to an embodiment.

FIG. 11 illustrates one possible example of metrology signal calibration, according to an embodiment.

FIG. 12 illustrates a flank scan on an example feature comprising a warped, single line structure, according to an embodiment.

FIG. 13 illustrates a flank scan on a warped line structure (e.g., similar to and/or the same as the line structure shown in FIG. 12), but with other surrounding pattern features (“clutter”), according to an embodiment.

FIG. 14 illustrates data from an application of a paired (parallel) flank scanning method described herein, according to an embodiment.

FIG. 15 is a block diagram of an example computer system, according to an embodiment.

FIG. 16 is a schematic diagram of a lithographic projection apparatus similar to FIG. 1, according to an embodiment.

FIG. 17 is a more detailed view of the apparatus in FIG. 16, according to an embodiment.

FIG. 18 is a more detailed view of the source collector module of the apparatus of FIG. 16 and FIG. 17, according to an embodiment.

### DETAILED DESCRIPTION

In semiconductor device manufacturing, determining alignment typically includes determining the position of an alignment mark (or marks) in a layer of a semiconductor device structure. Alignment is typically determined by irradiating an alignment mark with radiation, and comparing characteristics of different diffraction orders of radiation reflected from the alignment mark. Similar techniques are used to measure overlay and/or other parameters. In order to meet smaller and smaller node sizes, smaller and smaller metrology (e.g., alignment, overlay, etc.) marks are needed. Currently, metrology marks such as alignment marks can have resolution sizes as small as 40-50 μm. However, 30 μm or smaller marks are desired. Smaller marks facilitate placement of multiple marks in a field with a limited area, placement of marks within (e.g., half) a scribe line, placement of device structures in newly available areas no longer needed for alignment or other metrology marks, and/or placement of marks closer to the edges of a substrate. Unfortunately, there are currently no available techniques to make marks this small that can be used for semiconductor manufacturing and/or other purposes (e.g., even if a mark this small is able to be fabricated, it causes metrology, throughput, accuracy, compatibility, noise, pitch detectability, and/or other issues in a semiconductor manufacturing process).

Advantageously, the present system(s) and method(s) utilize existing structures in a patterned substrate (e.g., a semiconductor wafer), instead of dedicated alignment structures, to generate metrology signals. The systems and methods described here are faster and generate more information than typical methods. Scanning is performed faster and is configured to generate more information than in typical systems for generating metrology signals because the scanning is performed on an existing feature and continuously samples deformation across a large region of the substrate (semiconductor wafer), rather than a series of discrete alignment marks, and because the feature spans an interior of a device die, without causing processing and/or packaging issues. For example, currently chip designers only put alignment marks in scribe lanes, not in product dies. This is mainly because 1) the alignment marks only have temporary value and compete with space for transistors and other product features, and 2) the mismatch in feature size and pattern density between product and alignment marks often cause polishing steps to locally deform the product and the alignment marks since the polishing step is most stable when it has a uniform surface to work on. “Packaging” means that chip process designers have to fit a large number of metrology targets (alignment, overlay, yield testing structures) in a scribe lane, so they cannot afford to waste space by putting large gaps between targets. So traditional alignment marks need to be large enough to ensure the illumination spot doesn't land on the surrounding structures as it biases the position in a nondeterministic way.

By way of a brief introduction, the description herein relates generally to semiconductor device manufacturing and patterning processes. More particularly, the following paragraphs describe several components of a system and/or related systems. As described above these systems and methods may be used for measuring alignment in a semiconductor device manufacturing process, for example, or for other operations.

Although specific reference may be made in this text to the measurement of alignment and the manufacture of integrated circuits (ICs) for semiconductor devices, it should be understood that the description herein has many other possible applications. For example, it may be employed in the measurement of overlay and/or other parameters. It may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

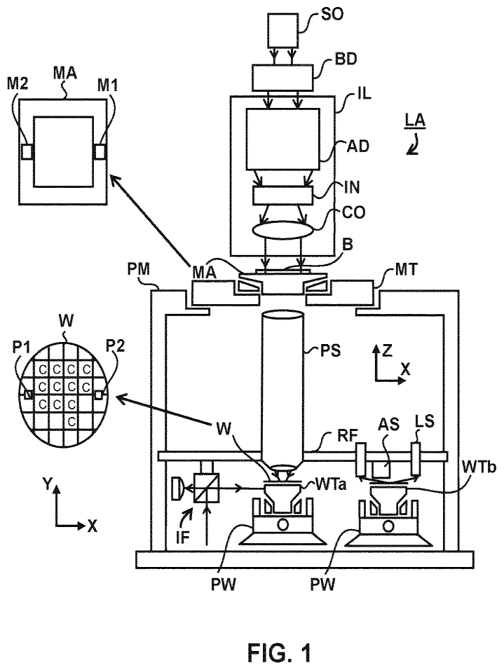

FIG. 1 schematically depicts an embodiment of a lithographic apparatus LA. The apparatus comprises an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation.

Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein with respect to lithography encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

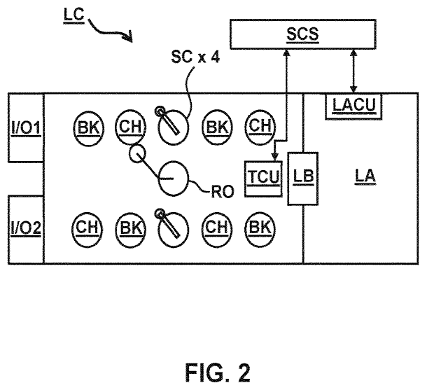

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on a dedicated metrology target provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. As discussed above, a fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. Traditionally, this may be termed diffraction-based metrology. One such application of this diffraction-based metrology is in the measurement of alignment. For example, alignment can be measured by comparing parts of the diffraction spectrum (for example, comparing different diffraction orders in the diffraction spectrum of a periodic grating).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non- optical imaging (e.g., scanning electron microscopy (SEM)). The SMASH (SMart Alignment Sensor Hybrid) system, as described in U.S. Pat. No. 6,961,116, which is incorporated by reference herein in its entirety, employs a self-referencing interferometer that produces two overlapping and relatively rotated images of an alignment marker, detects intensities in a pupil plane where Fourier transforms of the images are caused to interfere, and extracts the positional information from the phase difference between diffraction orders of the two images which manifests as intensity variations in the interfered orders.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus LA or the lithocell LC, or may be a stand-alone device.

To enable the metrology, often one or more targets are specifically provided on the substrate. A target may include an alignment mark, for example, and/or other targets. Typically, the target is specially designed and may comprise a periodic structure. For example, the target on a substrate may comprise one or more 1-D periodic structures (e.g., geometric features such as gratings), which are printed such that after development, the periodic structural features are formed of solid resist lines. As another example, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

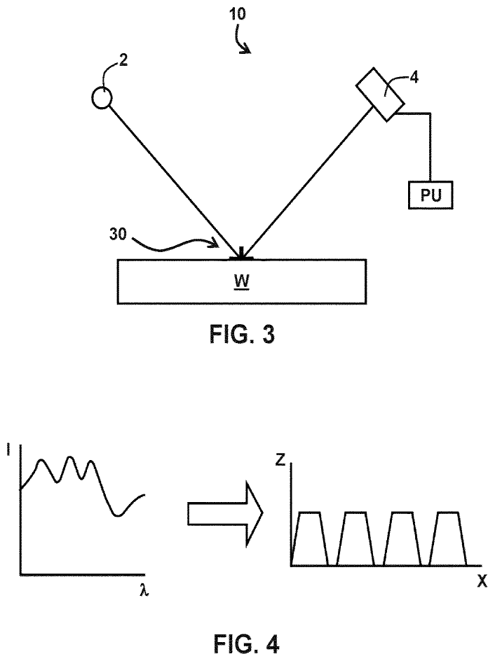

FIG. 3 depicts an example inspection system 10 that may be used to detect alignment and/or perform other metrology operations. It comprises a radiation source projector 2 which projects or otherwise irradiates radiation onto a substrate W (e.g., which may typically include an alignment mark). The redirected radiation is passed to a sensor such as a spectrometer detector 4 and/or other sensors, which measures a spectrum (intensity as a function of wavelength) of the specular reflected and/or diffracted radiation, as shown, e.g., in the graph on the left of FIG. 4. The sensor may generate an alignment signal conveying alignment data indicative of properties of the reflected radiation. From this data, the structure or profile giving rise to the detected spectrum may be reconstructed by one or more processors PU, a generalized example of which is shown in FIG. 4, or by other operations. Note that these are generalized examples. Often, illumination of a target such as an alignment mark is done orthogonal to the target and/or mark, and not at an angle as shown in these figures.

As in the lithographic apparatus LA in FIG. 1, one or more substrate tables (not shown in FIG. 4) may be provided to hold the substrate W during measurement operations. The one or more substrate tables may be similar or identical in form to the substrate table WT (WTa or WTb or both) of FIG. 1. In an example where inspection system 10 is integrated with the lithographic apparatus, they may even be the same substrate table. Coarse and fine positioners may be provided and configured to accurately position the substrate in relation to a measurement optical system. Various sensors and actuators are provided, for example, to acquire the position of a target portion of interest of a structure (e.g., an alignment mark), and to bring it into position under an objective lens. Typically, many measurements will be made on target portions of a structure at different locations across the substrate W. The substrate support can be moved in X and Y directions to acquire different targets, and in the Z direction to obtain a desired location of the target portion relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and the substrate moves. Provided the relative position of the substrate and the optical system is correct, it does not matter in principle which one of those is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

For typical alignment measurements, a target (portion) 30 on substrate W may be a 1-D grating, which is printed such that after development, the bars are formed of solid resist lines (e.g., which may be covered by a deposition layer), and/or other materials. Or the target 30 may be a 2-D grating, which is printed such that after development, the grating is formed of solid resist pillars, and/or other features in the resist.

The bars, pillars, vias, and/or other features may be etched into or on the substrate (e.g., into one or more layers on the substrate), deposited on a substrate, covered by a deposition layer, and/or have other properties. Target (portion) 30 (e.g., of bars, pillars, vias, etc.) is sensitive to changes in processing in the patterning process (e.g., optical aberration in the lithographic projection apparatus such as in the projection system, focus change, dose change, etc.) such that process variation manifests in variation in target 30. Accordingly, the measured data from target 30 may be used to determine an adjustment for one or more of the manufacturing processes, and/or used as a basis for making the actual adjustment.

For example, the measured data from target 30 may indicate alignment for a layer of a semiconductor device. The measured data from target 30 may be used (e.g., by the one or more processors) for determining one or more semiconductor device manufacturing process parameters based the alignment, and determining an adjustment for a semiconductor device manufacturing apparatus based on the one or more determined semiconductor device manufacturing process parameters. In some embodiments, this may comprise a stage position adjustment, for example, or this may include determining an adjustment for a mask design, a metrology target (e.g., an alignment mark) design, a semiconductor device design, an intensity of the radiation, an incident angle of the radiation, a wavelength of the radiation, a pupil size and/or shape, a resist material, and/or other process parameters.

Angle resolved scatterometry is useful in the measurement of asymmetry of features in product and/or resist patterns. A particular application of asymmetry measurement is for the measurement of alignment. The base concepts of asymmetry measurement using system 10 of FIG. 3 are described, for example, in U.S. patent application publication US2006-066855, which is incorporated herein in its entirety. In brief, for an alignment measurement, the positions of the diffraction orders in the diffraction spectrum of the target are determined by the periodicity of the target (e.g., alignment mark). Asymmetry in the diffraction spectrum is indicative of asymmetry in the individual features which make up the target. For example, any regions, from a significant fraction of an exposure field, to a whole exposure field, are useful regions for more accurate intrafield alignment fitting. In addition, the same feature present in any fields which lie along a straight line, can be captured in a continuous scan across most or all of the wafer size, provide more accurate interfield alignment fitting.

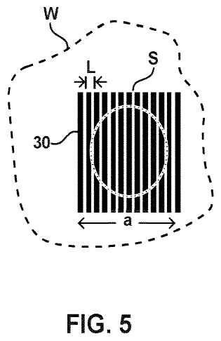

FIG. 5 illustrates a plan view of a typical target (e.g., alignment mark) 30, and the extent of a radiation illumination spot S in the system of FIG. 4. Typically, to obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target, in other words, is ‘underfilled’ by the illumination, and the diffraction signal is essentially free from any signals from product features and the like outside the target itself. The illumination arrangement may be configured to provide illumination of a uniform intensity across a back focal plane of an objective, for example. Alternatively, by, for example, including an aperture in the illumination path, illumination may be restricted to on axis or off axis directions.

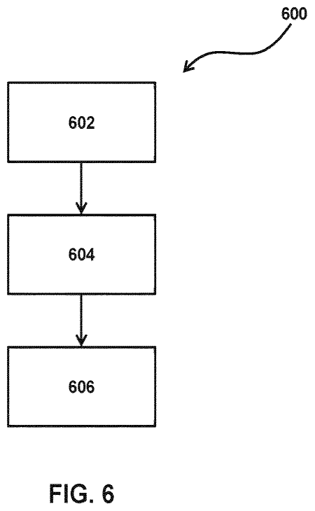

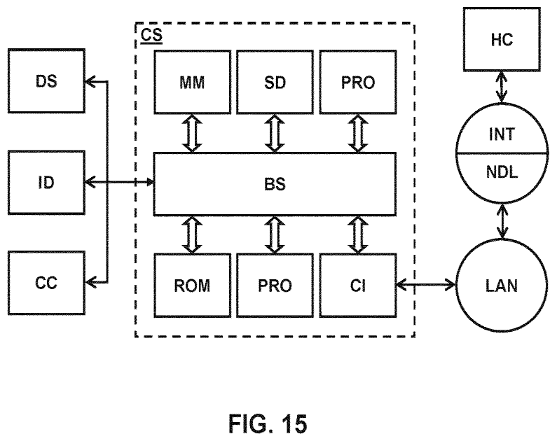

FIG. 6 illustrates a method 600 for generating a metrology signal. In some embodiments, generating the metrology signal is performed as part of a semiconductor device manufacturing process. In some embodiments, one or more operations of method 600 may be implemented in or by system 10 illustrated in FIGS. 3 and 4, a computer system (e.g., as illustrated in FIG. 15 and described below), and/or in or by other systems, for example. In some embodiments, method 600 comprises irradiating (operation 602) a feature in a patterned substrate with radiation, detecting (operation 604) reflected radiation from the feature, generating (operation 606) the metrology signal based on the detected radiation, and/or other operations. Method 600 is described below in the context of alignment, but this is not intended to be limiting. Method 600 may be generally applied to a number of different processes.

The operations of method 600 presented below are intended to be illustrative. In some embodiments, method 600 may be accomplished with one or more additional operations not described, and/or without one or more of the operations discussed. For example, in some embodiments, method 600 may include an additional operation comprising determining an adjustment for a semiconductor device manufacturing process. Additionally, the order in which the operations of method 600 are illustrated in FIG. 6 and described below is not intended to be limiting.

In some embodiments, one or more portions of method 600 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 600 in response to instructions stored electronically on an electronic storage medium. The one or more processing devices may include one or more devices configured through hardware, firmware, and/or software to be specifically designed for execution of one or more of the operations of method 600 (e.g., see discussion related to FIG. 15 below).

Operation 602 comprises irradiating a feature in a patterned substrate with radiation. The feature comprises a target portion of a patterned substrate (e.g., as described above related to FIG. 3-5), but is different than a dedicated alignment mark (e.g., a diffraction grating). The feature is different than a dedicated alignment structure and other structures that lie near the feature and within an illumination spot. The feature comprises one or more structures in the patterned substrate capable of providing a diffraction signal. In some embodiments, the feature can be any structure in a pattern design layout capable of generating a wide angle diffraction signal.

The feature may be included in a layer of a substrate in a semiconductor device structure, for example. In some embodiments, the feature comprises a geometric feature such as a 1D or 2D feature, and/or other geometric features. By way of several non-limiting examples, the feature may comprise a line, an edge, a fine-pitched series of lines and/or edges, and/or other features. In some embodiments, a fine-pitch has a pitch dimension of less than one micrometer, for example. In some embodiments, the feature (e.g., the line, edge, series, etc.) has a length spanning a region of measurement interest (e.g., a region larger than a normal target, such as the width/length of a die, but can be as long as a full wafer diameter).

The radiation may have a target wavelength and/or wavelength range, a target intensity, and/or other characteristics. The target wavelength and/or wavelength range, the target intensity, etc., may be entered and/or selected by a user, determined by the system based on previous alignment measurements, and/or determined in other ways. In some embodiments, the radiation comprises light and/or other radiation. In some embodiments, the light comprises visible light, infrared light, near infrared light, and/or other light. In some embodiments, the radiation may be any radiation appropriate for interferometry.

The radiation may be generated by a radiation source (e.g., projector 2 shown in FIGS. 3 and 4 and described above). In some embodiments, the radiation may be directed by the radiation source onto a feature, sub-portions (e.g., something less than the whole) of a feature, multiple features, and/or onto the substrate in other ways. In some embodiments, the radiation may be directed by the radiation source onto the feature in a time varying manner. For example, the radiation may be rastered over a feature such that different portions of the feature are irradiated at different times. As another example, characteristics of the radiation (e.g., wavelength, intensity, etc.) may be varied. This may create time varying data envelopes, or windows, for analysis. The data envelopes may facilitate analysis of individual sub-portions of a feature, comparison of one portion of a feature to another and/or to other features, and/or other analysis.

Operation 604 comprises detecting reflected radiation from the feature. Detecting reflected radiation comprises detecting one or more phase and/or amplitude (intensity) shifts in reflected radiation from one or more geometric features. The one or more phase and/or amplitude shifts correspond to one or more dimensions of a feature. For example, the phase and/or amplitude of reflected radiation from one side of a feature is different relative to the phase and/or amplitude of reflected radiation from another side of the feature.

Detecting the one or more phase and/or amplitude (intensity) shifts in the reflected radiation from the feature comprises measuring local phase shifts (e.g., local phase deltas) and/or amplitude variations that correspond to different portions of a feature. For example, the reflected radiation from a specific area of a feature may comprise a sinusoidal waveform having a certain phase and/or amplitude. The reflected radiation from a different area of the feature may also comprise a sinusoidal waveform, but one with a different phase and/or amplitude. Detected reflected radiation also comprises measuring a phase and/or amplitude difference in reflected radiation of different diffraction orders. Detecting the one or more local phase and/or amplitude shifts may be performed using Hilbert transformations, for example, and/or other techniques. Interferometry techniques and/or other operations may be used to measure phase and/or amplitude differences in reflected radiation of different diffraction orders.

The irradiating (operation 602) and the detecting (operation 604) comprises scanning. The scanning is performed faster and is configured to generate more information than in typical systems for generating metrology signals because the scanning is performed on a feature that is already part of a pattern design layout (e.g., compared to an alignment mark which is added as an extra portion of a pattern), the scanning continuously samples across a large region of a field or wafer rather than a series of discrete alignment marks, the scanned feature is configured to span an interior of device dies without causing processing and packaging issues, and/or for other reasons.

As described above, the scanning is continuous. Continuous scanning is advantageous because it removes the need for any preparation steps required for each individual scan, which can on the order of the scan time itself. Continuous scanning comprises substantially uninterrupted rastering of a beam of radiation along or across a feature. This enables substantially continuous sampling of deformation and/or other dimensional characteristics across a relatively large region of the substrate (semiconductor wafer) under a stable, constant velocity. This contrasts with scanning a series of discrete alignment marks, for example, where slow scans or staring are required to ensure the signal stays below the detector cutoff limits and where most time is spent accelerating and deaccelerating the wafer stage as opposed to capturing optical signals. This makes the current process faster than typical methods. Scanning is performed faster because the scanning is performed on an existing feature and continuously samples deformation across a large region of the substrate (semiconductor wafer), rather than a series of discrete alignment marks.

The scanning may have a radiation beam trajectory across the feature. A radiation beam trajectory across the feature may comprise a pathway the radiation beam follows when it is rastered across the feature. For example, the radiation beam may be controlled to follow a certain path relative to a feature. The radiation beam trajectory may be fed to measurement systems such as the ASML SMASH and/or Orion systems, for example. The radiation beam trajectory may be configured such that the scanning is performed: perpendicular to the feature; along one side of the feature, wherein a spot size of the radiation is configured to cover the one side of the line and/or edge feature; along both sides of the feature, wherein the spot size of the radiation is configured to cover both sides of the feature at the same time; and/or in other ways.

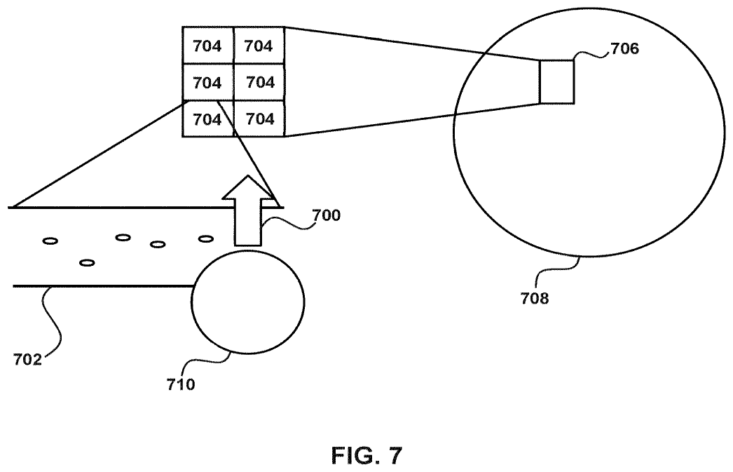

By way of a non-limiting example, FIG. 7 illustrates a first possible version of scanning where the radiation beam trajectory 700 is perpendicular to a feature 702. In this example, feature 702 is a scribe line shown with reference to a die 704 (e.g., and/or corresponding reticle/mask) for a field 706 on a substrate or wafer 708. FIG. 7 illustrates how radiation spot 710 travels along trajectory 700 across scribe line (feature) 702. FIG. 7 illustrates a perpendicular isolated line scan. This can capture the scribe line directly, for example.

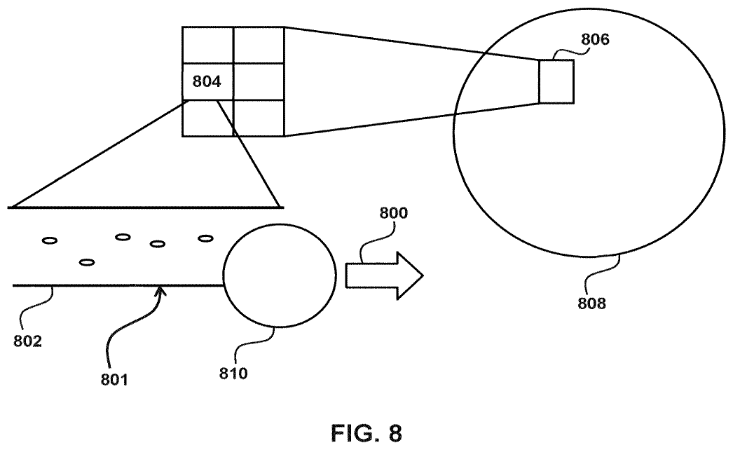

By way of a second non-limiting example, FIG. 8 illustrates a second possible version of scanning where the radiation beam trajectory 800 follows one edge 801 of a feature 802. In this example, feature 802 is again a scribe line shown with reference to a die 804 (e.g., and/or corresponding reticle/mask) for a field 806 on a substrate or wafer 808. FIG. 8 illustrates how radiation spot 810 travels along trajectory 800 at one edge of scribe line (feature) 802. FIG. 8 illustrates a parallel isolated line scan. The spot size of spot 810 can capture one edge of the scribe line, and can be scanned at any speed, allowing the capture of longer scale variations across wafer 808, for example. In this example, measurement information (e.g., feature dimensions, feature location, and/or other alignment related information) may be generated by interfering a diffraction pattern produced by edge 801 with itself, and/or other operations.

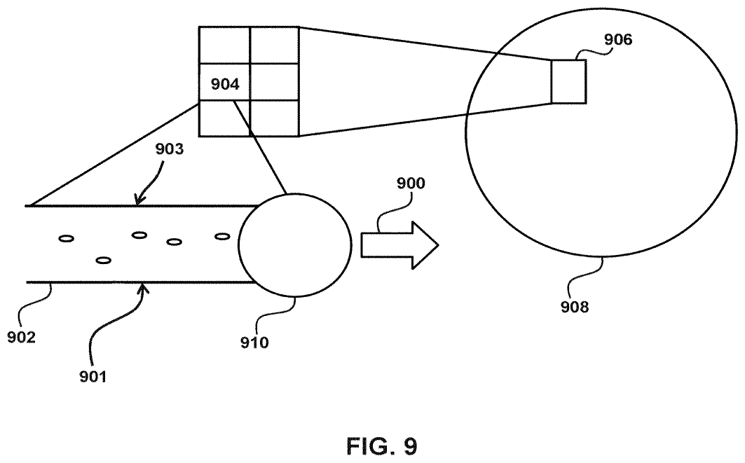

By way of a third non-limiting example, FIG. 9 illustrates a third possible version of scanning where the radiation beam trajectory 900 follows both edges 901, 903 of a feature 902. In this example, feature 902 is again a scribe line shown with reference to a die 904 (e.g., and/or corresponding reticle/mask) for a field 906 on a substrate or wafer 908. FIG. 9 illustrates how radiation spot 910 travels along trajectory 900 and encompasses both edges of scribe line (feature) 902. FIG. 9 illustrates a parallel isolated line scan between two scribe lines. The spot size of spot 910 is large enough to capture both edges of the scribe line, increasing a lateral scan offset sensitivity. In this example, measurement information (e.g., feature dimensions, feature location, and/or other alignment related information) may be generated by interfering a diffraction pattern produced by one edge 901 with a diffraction pattern produced by the other edge 903, and/or other operations.

In some embodiments, the scanning is performed at a predefined scan speed for a given sampling rate. The predefined scan speed and/or given sampling rate are determined based on a size of the feature and/or other information. In some embodiments, the predefined scan speed and/or given sampling rate are adjustable based on the size and/or other characteristics of the feature. In some embodiments, conversely, sizes of features that can be scanned are determined based on a ratio of the predefined scan speed to the given sampling rate.

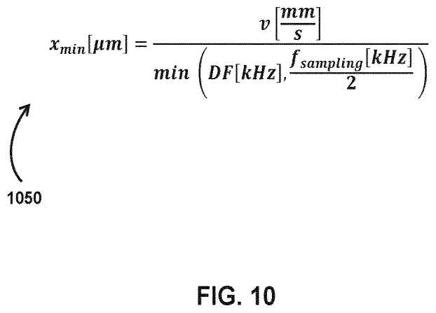

For example, the relationship between the scan speed, sampling rate, and feature size may be defined by an equation the same as or similar to Equation 1050 shown in FIG. 10. In Equation 1050, xₘᵢₙ is the minimum scannable feature size, v is the scan speed, f_{sampling} is the sampling frequency and DF is the anti-aliasing filter/detection frequency metrology system. Various example units (e.g., μm, mm/s, kHz) are shown in Equation 1050, but this is not intended to be limiting. As shown in FIG. 10, using the present systems and methods, one is able to measure as small of a feature as desired, by scanning the feature at a pre-defined scan speed given a minimum sampling rate of the metrology system. In other words, by changing the scan speed, the present systems and methods may be used to measure relatively small features that are part of a design layout, instead of larger, specially designed alignment marks added to the design layout for metrology purposes.

Advantageously, using one of the techniques described in FIG. 7-9, in combination with Equation 1050 shown in FIG. 10, does not require additional real estate on a substrate for dedicated alignment marks. These techniques can expand to print controlled lines and/or dual use CMP dams. Throughput can be increased relative to prior metrology processes. These techniques are flexible to spot size and sensor type. These techniques can still be used even with shrinking scribe lines (e.g., double edge interference as shown in FIG. 9), can be used to probe a variety of scan lengths (e.g., more than a single dedicated alignment mark), can be used for a two dimensional scan (e.g., perpendicular to a scribe line direction) for improved noise and fitting features, and/or have other advantages.

Returning to FIG. 6, operation 606 comprises generating a metrology signal based on the detected reflected radiation from the feature. The metrology signal comprises measurement information pertaining to the feature. For example, the metrology signal may be an alignment signal comprising alignment measurement information, an overlay signal comprising overlay measurement information, and/or other metrology signals. In some embodiments, operation 606 includes determining, based on the metrology signal, an alignment inspection location of the feature. The measurement information (e.g., the alignment inspection location of the feature) may be determined using principles of interferometry and/or other principles.

The metrology signal comprises an electronic signal that represents and/or otherwise corresponds to the radiation reflected from the feature(s). The metrology signal may indicate an alignment value for the feature, for example, and/or other information. Generating the metrology signal comprises sensing the reflected radiation and converting the sensed reflected radiation into the electronic signal. In some embodiments, generating the metrology signal comprises sensing different portions of the reflected radiation from different areas and/or different geometries of the feature, and combining the different portions of the reflected radiation to form the metrology signal. This sensing and converting may be performed by components similar to and/or the same as detector 4, detector 18, and/or processors PU shown in FIG. 3 and FIG. 4, and/or other components.

In some embodiments, generating the metrology signal may comprising directly measuring the dimensions of a feature. For example, direct dimensional measurements of a feature may be made with a scatterometer and/or other systems. In some embodiments, direct dimensional measurements may be used in combination with, and/or instead of the local phase and/or amplitude shifts described herein, to determine the alignment of a feature. For example, output dimensional measurements from the scatterometer system may be provided to processor PU (FIG. 3) and/or other system components, which may generate the metrology signal based at least in part on the output dimensional measurements from the scatterometer system.

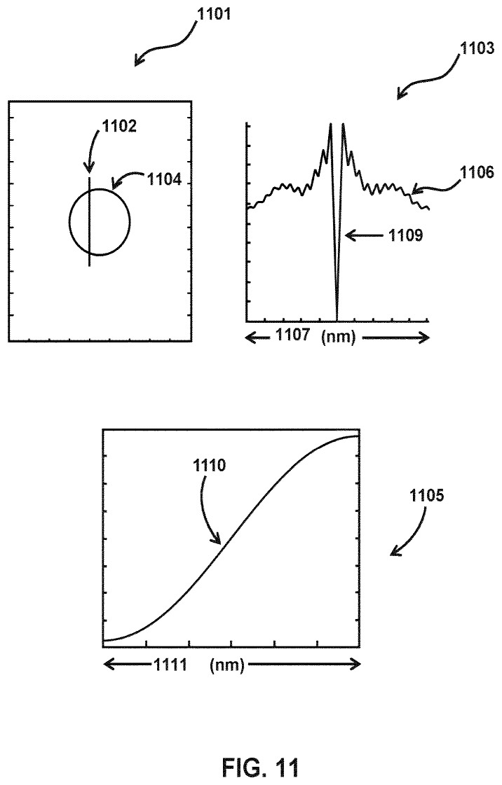

In some embodiments, the metrology signal is calibrated based on a scan of the feature isolated from other surrounding structures. In some embodiments, the metrology signal is calibrated based on a perpendicular or parallel line scan. Once calibrated, the metrology signal can be configured in several different ways. For example, in some embodiments, the metrology signal comprises a signal from a parallel flank scan. The signal from a flank scan comprises diffraction oriented perpendicular from a scan direction. The signal from the parallel flank scan comprises a difference between a signal from a first scan of the feature and a second parallel scan of the feature. In some embodiments, the metrology signal comprises a signal from two parallel flank scans on two corresponding features from two different regions of a substrate. The signal from the two parallel flank scans comprises a difference between a first signal from a first parallel flank scan from a first region and a second signal from a second parallel flank scan from a second region. A given signal from a given parallel flank scan comprises a difference between a signal from a first scan of the feature and a second parallel scan of the feature, where different regions comprise different dies on one substrate or the same dies between different substrates. Calibration and some of the possible configurations of the metrology signal are further described below related to FIG. 11-14. It should be noted that the dimensions, speeds, frequencies, configurations of the metrology signal, etc., described as part of FIG. 11-14 are examples only and are not intended to be limiting. Other possible dimensions, speeds, frequencies, configurations of the metrology signal, etc., are contemplated.

FIG. 11 illustrates one possible example of metrology signal calibration. In FIG. 11, a simulation of a destructive interference perpendicular scan (e.g., a perpendicular isolated line scan) for a 0.4 μm wide line 1102 (e.g., one possible example of a feature described herein) is shown in view 1101 (e.g., spot 1104 moves horizontally across line 1102). View 1103 illustrates a calibration signal 1106 at a detector and how signal 1106 changes with position 1107 (relative to line 1102 as spot 1104 traverses line 1102). A filter may be applied to signal 1106 based on the detector, but since (in this example) this is a slow scan (e.g., at 11 mm/s), the filter does not modify signal 1106. The simulation of the detector uses two filters in this example, a 2nd order Bessel low pass filter with a 120 kHz cutoff frequency, and then a resampling to the 20-320 kHz sampling rates which are available including an anti-aliasing 8th order Finite Impulse Response with cutoff at half the sampling rate. For this simulation, 320 kHz sampling was selected. The central portion 1109 of signal 1106 (e.g., where signal 1106 is changing quickly but consistently so that the shape of signal 1106 appears as a parabola) may form a calibration basis for later scans.

View 1105 of FIG. 11 illustrates a derived calibration curve 1110 (at given calibration offsets 1111) for a paired flank scan (described below) based on the simulation shown in views 1101 and 1103. As described above, a useful part of signal 1106 for calibration is portion 1109 (e.g., the inner ˜+/−170 nm in this example) where signal 1106 is changing sharply and smoothly. Curve 1110 is derived by sampling portion 1109 and plotting sampled points. (A series of subalignment-resolution lines (<<1.6 nm pitch) may look similar, for example.) This sampling and plotting may effectively broaden portion 1109. This curve is based off a perpendicular scan of a version of the target feature, but one isolated from surroundings. Portion 1109 is useful because the position offset and interfered intensity signal are linear and stable. By taking the derivative or finite difference across the span of the parallel flank scan offsets, curve 1110 results, which is a direct relation between position offset of the alignment feature from the spot center and the measured, interfered intensity level.

Turning to scanning such lines (e.g., features) in a parallel direction (e.g., a direction along or parallel to a given feature), basics of this type of scan are described in European patent EP2131243B1, which is incorporated by reference in its entirety, where this type of scan was called a “flank scan”. In some embodiments, with this type of scan, two parallel scans may be more useful than one parallel scan. A first parallel scan may follow a first scan path (along a feature), and a second parallel scan may follow a second scan path, that is offset from the first scan path in a specific direction by a specific amount (e.g., also along the same feature, but offset by a small amount relative to the first scan path so that the second scan is performed along the same feature but not in the same location as the first scan). By taking the difference of the two signals from the two parallel scans, a capture range may be extended to allow unambiguous scans on either the dropping or rising side of the inner signal (e.g., portion 1109 described above) and facilitate more flexibility in the presence of a background, which will cancel out. The two parallel scans comprise a “paired flank scan”. A benefit of these flank scans together with high scan velocities (e.g., which are possible because a scan follows a continuous line and/or other feature as described above) is that this facilitates matching signal frequencies to a detector bandwidth which, is impossible for normal alignment marks. Normal alignment marks need to be scanned at ˜8-22 mm/s scan speed to permit small enough signal frequencies, ˜6-28 kHz, so that the sensor system can adequately capture data. Higher signal frequencies start to suffer from a declining sensor transfer function amplitude. However, a nominally straight line (and/or other features as described herein) cause a flat signal and not lose signal at larger scan speeds. As a specific example, wafer (substrate) stage scan speeds on for exposure are commonly 700-900 mm/s, which is the likely range for this type of scan. As described herein, the present systems and methods facilitate metrology on features with or without surrounding structures (e.g., a line by itself and/or a line with several other nearby features).

With the present systems and methods, metrology throughput is roughly neutral compared to metrology throughput for sampling traditional alignment marks to fit a 3rd order intra-field model, for example. Fitting 20 terms would require at least four vertical and four horizontal scans over a field (with multiple, >=4 resolution elements per scan). Depending on the design layout, either scanning the same field or neighboring ones, each move between scans would spend about 30-80 ms with a DUV stage, for example. Each scan would take about 40 ms. This totals to about 500-900 ms. Paired flank scans (e.g., as described herein) for a full field takes approximately 1000-1800 ms. Compare this to scanned 10 BF (or CB) marks distributed over a field which would take about 500 ms to scan if scanned back-to-back. There may be further optimizations involving routings that are possible.

A difficulty in measuring features in a patterned substrate is that the spot size of the radiation used for inspection usually covers other, uncontrolled structures, for example other alignment marks, overlay targets, and/or other product features. This creates noise or other unwanted portions of a measured signal that can overwhelm a desired portion of the signal (e.g., the portion of the signal corresponding to the desired metrology target). The present systems and methods overcome this and other difficulties.

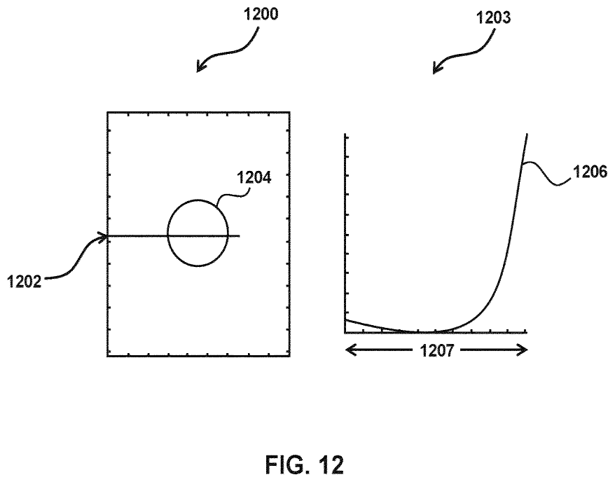

For example, FIG. 12 illustrates a flank scan 1200 on an example feature comprising a warped, single line 1202 structure. In scan 1200, radiation spot 1204 travels along or substantially parallel to line 1202. This structure may be part of a semiconductor product and/or any other portion of a patterned substrate (e.g., wafer). Plot 1203 illustrates a metrology signal 1206 at a detector and how signal 1206 changes with position 1207 (relative to line 1202 as spot 1204 travels along line 1202). Note that signal 1206 is clean and smooth, without variation cause by cluttering structures at or near line 1202 in a patterned substrate. In this and following examples, an arbitrary, fixed detector gain is assumed.

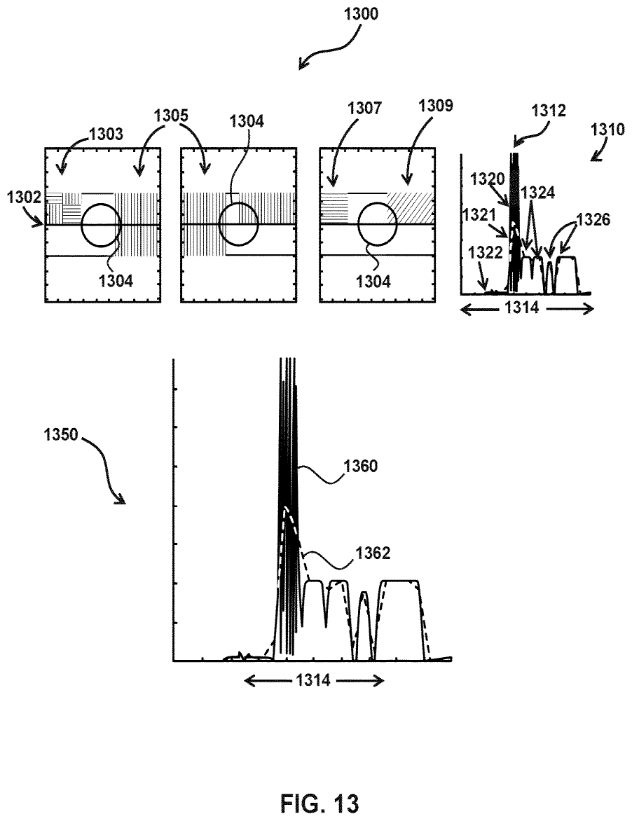

FIG. 13 illustrates a flank scan 1300 on a warped line 1302 structure (e.g., similar to and/or the same as line 1102 structure shown in FIG. 11 and line 1202 structure shown in FIG. 12), but with other surrounding pattern features (“clutter”) 1303, 1305, 1307, and 1309. In scan 1300, radiation spot 1304 travels along or substantially parallel to line 1302. FIG. 13 also illustrates plot 1310, which illustrates a metrology signal 1312 at a detector and how signal 1312 changes with position 1314 (relative to line 1302 and clutter 1303-1309 as spot 1304 travels along line 1302). Note that signal 1312 is noisy, with variation 1320, 1322, 1324, and 1326 causes by clutter 1303-1309 at or near line 1302 in the patterned substrate. If this data can be fit accurately enough, it would be a means to directly fit absolute field distortion, for example. In this example, signal 1312 is sampled at 20 kHz and conditioned with a low pass antialiasing filter to try to suppress high frequency noise from the background, which helps to better define signal 1312 for metrology purposes, but is not enough by itself (in this example). Dotted line 1321 shows a filtered version of the signal. Line 1321 illustrates how low pass filtering can help suppress the influence of the clutter without losing the resolution from the main signal. Low pass filtering may be combined with other operations like the parallel flank scans and multi-field or multi-substrate relative methods to achieve added accuracy.

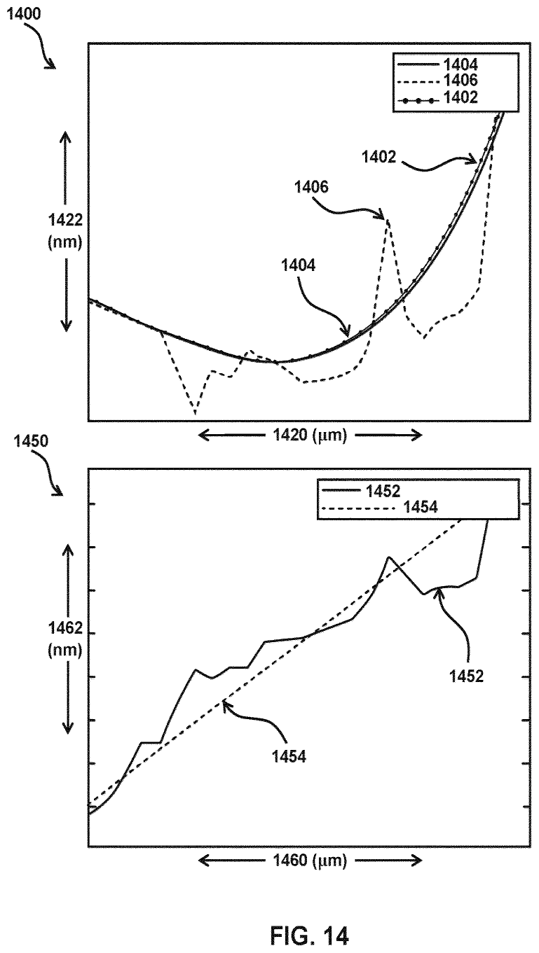

Plot 1350 of FIG. 3 illustrates a signal 1352 from a repetition of the same scan 1300, but now with a −20 nm y-offset (e.g., a paired (parallel) flank scan), for example. Plot 1350 illustrates raw 1360 and filtered 1362 versions of signal 1352. Plot 1350 demonstrates that a paired (parallel) flank scan can be used to remove unwanted noise and/or other variation since this small offset sees a very similar background as the first scan but a significantly different main signal. This removal may be performed by, for example, subtracting one signal from another to determine a different between signals as described herein, and/or with other operations. Note that 1310 and 1350 look very similar in terms of their clutter signal. The underlying signal difference is difficult to see in the broad view in FIG. 13, but the difference—1406 in FIG. 14 (described below)—is a practical way to visualize the difference.

FIG. 14 illustrates data from an application of the paired (parallel) flank scanning described above. FIG. 14 illustrates a plot 1400 with a calibration signal 1402 compared to a signal 1404 from a clutter free scan, and a signal 1406 from a scan with background clutter. Plot 1400 shows scan offset 1420 on the x-axis, and non-scan offset 1422 on the y-axis. Signal 1404 is highly accurate (e.g., it lies almost on top of signal 1402), but the clutter introduces an average of 7.5 nm offset in signal 1406 in this example. This would normally be too large for intra-field corrections in a semiconductor manufacturing process, although the offset depends on the actual surrounding structures and their regularity across a field (which could increase or decrease the offset). Additional and/or optimized filtering may also have an effect.

In some embodiments, multiple parallel flank scans may be used. Most of the noise introduced by surrounding structures (clutter) may cancel out (e.g., may be removed) using a signal from a paired (parallel) flank scan (e.g., by subtracting one signal from another in the pair)—as shown in FIG. 13. However, for arbitrary surrounding structures, a metrology signal from a paired (parallel) flank scan may still be too noisy for general application.

Plot 1450 of FIG. 14 illustrates a difference in a measured non-scan offset for two paired (parallel) flank scan signals 1452 with the same surrounding structures (clutter) but different intra-field warping functions, relative to a calibration signal 1454. Plot 1450 shows scan offset 1460 on the x-axis, and difference in measured non-scan offset 1462 on the y-axis. Using paired flank scans and applying a calibration signal from a central region of a perpendicular isolated line scan (e.g., as described above), the recovered offset (e.g., the difference in a measured non-scan offset for two paired (parallel) flank scan signals 1452) between the two warped lines (e.g., from different wafers or regions of a wafer) compared to calibration signal 1454 is sub-nanometer, and accurate enough for intra-field wafer alignment in a semiconductor manufacturing process. By this means, a relative correction between different fields or substrates with the required accuracy can be achieved. Specifically, the average error in position over this plausible resolution element is 17 pm, which is sufficient relative accuracy for all of the latest semiconductor manufacturing processes. Furthermore, a resolution element of 1 mm permits intrafield models of orders up to 25-32, which are much higher that the 3^{rd} orders that are commonly used today. The different warping functions describe common design layout features (e.g., slightly warped lines as in the examples discussed above) with realistic wafer-to-wafer variation.

As a brief review, in some embodiments, the metrology signal comprises a signal from a parallel flank scan. The signal from a flank scan comprises diffraction oriented perpendicular from a scan direction. The signal from the parallel flank scan comprises a difference between a signal from a first scan of the feature and a second parallel scan of the feature. Summarizing the information presented in FIG. 14, in some embodiments, the metrology signal comprises a signal from two parallel flank scans on two corresponding features from two different regions of a substrate (e.g., wafer), or two substrates, etc.. The signal from the two parallel flank scans comprises a difference between a first signal from a first parallel flank scan from a first region and a second signal from a second parallel flank scan from a second region. A given signal from a given parallel flank scan comprises a difference between a signal from a first scan of the feature and a second parallel scan of the feature, where different regions comprise different dies on one substrate or the same dies between different substrates. Using paired (parallel) flank scans and applying a calibration signal (e.g., as described above), the difference in a measured non-scan offset for two paired (parallel) flank scan signals (e.g., 1452) between features (e.g., the two warped lines from different wafers or regions of a wafer) compared to calibration signal 1454 is sub-nanometer, and accurate enough for intra-field wafer alignment in a semiconductor manufacturing process.

Returning to FIG. 6, in some embodiments, operation 606 comprises determining an adjustment for a semiconductor device manufacturing process. In some embodiments, operation 606 includes determining one or more semiconductor device manufacturing process parameters. The one or more semiconductor device manufacturing process parameters may be determined based on one or more detected phase and/or amplitude variations, an alignment value indicated by the metrology signal, dimensions determined by a scatterometer system, and/or other similar systems, and/or other information. The one or more parameters may include a parameter of the radiation (the radiation used for determining alignment), an alignment inspection location within a feature, an alignment inspection location on a layer of a semiconductor device structure, a radiation beam trajectory across a feature, and/or other parameters. In some embodiments, process parameters can be interpreted broadly to include a stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

A parameter of the radiation used for determining alignment, for example, may include a wavelength, an intensity, an angle of incidence, and/or parameters of the radiation. These parameters may be adjusted to better measure features with specific shapes, enhance the intensity of reflected radiation, increase and/or otherwise enhance (e.g., maximize) the phase and/or amplitude shifts (if any) in reflected radiation from one area of a feature to the next, and/or for other purposes. This may enable and/or enhance detection of more subtle deviations, make the phase and/or amplitude shifts easier to detect, and/or have other advantages.

In some embodiments, operation 606 includes determining a process adjustment based on the one or more determined semiconductor device manufacturing process parameters, adjusting a semiconductor device manufacturing apparatus based on the determined adjustment, and/or other operations. For example, if a determined alignment is not within process tolerances, the misalignment may be caused by one or more manufacturing processes whose process parameters have drifted and/or otherwise changed so that the process is no longer producing acceptable devices (e.g., alignment measurements may breach a threshold for acceptability). One or more new or adjusted process parameters may be determined based on the alignment determination. The new or adjusted process parameters may be configured to cause a manufacturing process to again produce acceptable devices. For example, a new or adjusted process parameter may cause a previously unacceptable alignment (or misalignment) to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of operation 606), for example. In some embodiments, operation 606 may include electronically adjusting an apparatus (e.g., based on the determined process parameters). Electronically adjusting an apparatus may include sending an electronic signal, and/or other communications to the apparatus, for example, that causes a change in the apparatus. The electronic adjustment may include changing a setting on the apparatus, for example, and/or other adjustments.

FIG. 15 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

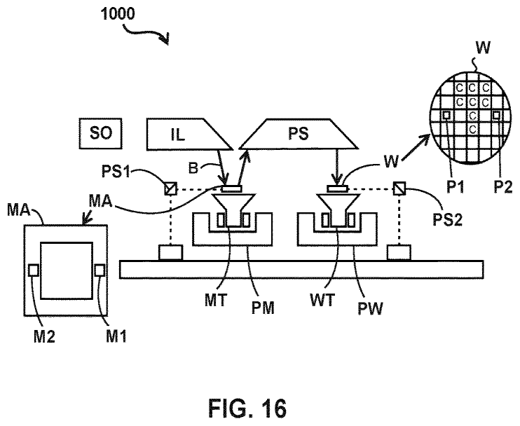

FIG. 16 schematically depicts an exemplary lithographic projection apparatus similar to and/or the same as the apparatus shown in FIG. 1 that can be used in conjunction with the techniques described herein. The apparatus 1000 comprises an illumination system IL, to condition a beam B of radiation. In this particular case, the illumination system also comprises a radiation source SO; a first object table (e.g., patterning device table) MT provided with a patterning device holder to hold a patterning device MA (e.g., a reticle), and connected to a first positioner PM (working in association with a first position sensor) PSI to accurately position the patterning device; a second object table (substrate table) WT provided with a substrate holder to hold a substrate W (e.g., a resist-coated silicon wafer), and connected to a second positioner PW (working in association with a second position sensor PS2) to accurately position the substrate; a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means for setting the outer and/or inner radial extent (commonly referred to as σ-outer and σ-inner, respectively) of the intensity distribution in the beam. In addition, it will generally comprise various other components, such as an integrator and a condenser. In this way, the beam B impinging on the patterning device MA has a desired uniformity and intensity distribution in its cross-section.

It should be noted with regard to FIG. 16 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam B subsequently intercepts the patterning device MA, which is held on a patterning device table MT. Having traversed the patterning device MA, the beam B passes through a lens, which focuses the beam B onto a target portion C of the substrate W. With the aid of the second positioning means (and interferometric measuring means), the substrate table WT can be moved accurately, e.g. to position different target portions C in the path of the beam B. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted. However, in the case of a stepper (as opposed to a step-and-scan tool) the patterning device table MT may just be connected to a short stroke actuator, or may be fixed.

The depicted tool (similar to or the same as the tool shown in FIG. 1) can be used in two different modes. In step mode, the patterning device table MT is kept essentially stationary, and an entire patterning device image is projected in one operation (i.e., a single “flash”) onto a target portion C. The substrate table WT is then shifted in the x and/or y directions so that a different target portion C can be irradiated by the beam B. In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

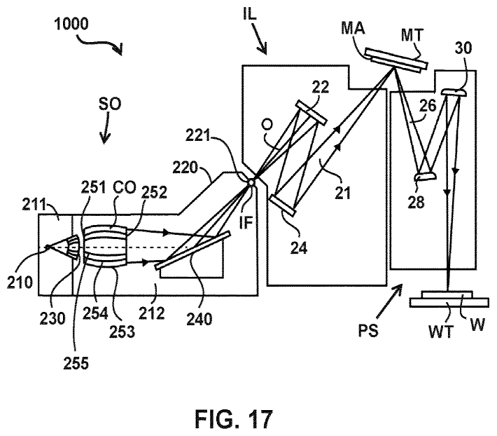

FIG. 17 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the hot plasma 210 is created to emit radiation in the EUV range of the electromagnetic spectrum. The plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap 230 further indicated herein at least includes a channel structure.

The source chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation beam 21 at the patterning device MA, held by the support structure MT, a patterned beam 26 is formed and the patterned beam 26 is imaged by the projection system PS via reflective elements 28, 330 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 17.

Collector optic CO, as illustrated in FIG. 17, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

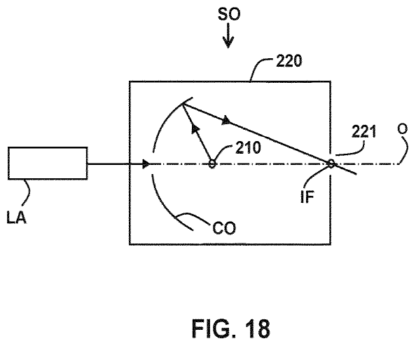

Alternatively, the source collector module SO may be part of an LPP radiation system as shown in FIG. 18. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

Various embodiments of the present systems and methods are disclosed in the subsequent list of numbered clauses:
1. A system for generating a metrology signal, the system comprising: a source configured to irradiate a feature in a patterned substrate with radiation, the feature being different than a dedicated alignment structure; a sensor configured to detect reflected radiation from the feature; and one or more processors configured to generate the metrology signal based on the detected reflected radiation from the feature, the metrology signal comprising measurement information pertaining to the feature.
2. The system of clause 1, wherein the feature comprises one or more structures in the patterned substrate capable of providing a diffraction signal.
3. The system of any of the previous clauses, wherein the feature is different than the dedicated alignment structure and other structures that lie near the feature and within an illumination spot.
4. The system of any of the previous clauses, wherein the irradiating and the detecting comprises scanning, and wherein the scanning is continuous.
5. The system of any of the previous clauses, wherein the feature is a structure capable of generating wide angle diffraction, and wherein the scanning is performed: perpendicular to the feature; along one side of the feature, wherein a spot size of the radiation is configured to cover the one side of the feature; or along both sides of the feature, wherein the spot size of the radiation is configured to cover both sides of the feature at the same time.
6. The system of any of the previous clauses, wherein the feature comprises a line, an edge, or a fine- pitched series of lines and/or edges, and wherein the feature has a length spanning a region of measurement interest.
7. The system of any of the previous clauses, wherein a fine-pitch has a pitch dimension of less than 1 micrometer.
8. The system of any of the previous clauses, wherein the irradiating and the detecting comprises scanning, and wherein the scanning is performed faster and is configured to generate more information than in typical systems for generating metrology signals because the scanning is performed on the feature and continuously samples deformation across a large region of a field or wafer rather than a series of discrete alignment marks, and because the feature is configured to span an interior of device dies without causing processing and packaging issues.
9. The system of any of the previous clauses, wherein the irradiating and the detecting comprises scanning, and wherein the scanning is performed faster and is configured to generate more information than in typical systems for generating metrology signals because the scanning is performed on the feature in the patterned substrate instead of on the dedicated alignment structure.
10. The system of any of the previous clauses, wherein the irradiating and the detecting comprises scanning, and wherein the metrology signal is calibrated based on a scan of the feature isolated from other surrounding structures.
11. The system of any of the previous clauses, wherein the irradiating and the detecting comprises scanning, wherein the metrology signal is calibrated based on a perpendicular or parallel line scan.
12. The system of any of the previous clauses, wherein the metrology signal comprises a signal from a parallel flank scan, a signal from a flank scan comprising diffraction oriented perpendicular from a scan direction, the signal from the parallel flank scan comprising a difference between a signal from a first scan of the feature and a second parallel scan of the feature.
13. The system of any of the previous clauses, wherein the metrology signal comprises a signal from two parallel flank scans on two corresponding features from two different regions, the signal from the two parallel flank scans comprising a difference between a first signal from a first parallel flank scan from a first region and a second signal from a second parallel flank scan from a second region, wherein a given signal from a given parallel flank scan comprises a difference between a signal from a first scan of the feature and a second parallel scan of the feature, where different regions comprise different dies on one substrate or the same dies between different substrates.
14. The system of any of the previous clauses, wherein the irradiating and detecting comprise scanning, and wherein the scanning is performed at a predefined scan speed for a given sampling rate, the predefined scan speed and/or given sampling rate determined based on a size of the feature.
15. The system of any of the previous clauses, wherein the predefined scan speed and/or given sampling rate are adjustable based on the size of the feature.
16. The system of any of the previous clauses, wherein sizes of features that can be scanned are determined based on a ratio of the predefined scan speed to the given sampling rate.
17. The system of any of the previous clauses, wherein the feature comprises a line and/or an edge, the dedicated alignment structure comprises a diffraction grating, and the line and/or edge feature forms a portion of a design layout, separate from the diffraction grating.
18. The system of any of the previous clauses, wherein the metrology signal is an alignment signal or an overlay signal.
19. The system of any of the previous clauses, wherein the one or more processors are further configured to determine, based on the metrology signal, an alignment inspection location of the feature.
20. The system of any of the previous clauses, wherein the feature is included in a layer of the substrate in a semiconductor device structure, and wherein the one or more processors are further configured to adjust a semiconductor device manufacturing process based on the metrology signal.
21. A method for generating a metrology signal, the method comprising: irradiating a feature in a patterned substrate with radiation, the feature being different than a dedicated alignment structure; detecting reflected radiation from the feature; and generating the metrology signal based on the detected reflected radiation from the feature, the metrology signal comprising measurement information pertaining to the feature.
22. The method of clause 21, wherein the feature comprises one or more structures in the patterned substrate capable of providing a diffraction signal.
23. The method of any of the previous clauses, wherein the feature is different than the dedicated alignment structure and other structures that lie near the feature and within an illumination spot.
24. The method of any of the previous clauses, wherein the irradiating and the detecting comprises scanning, and wherein the scanning is continuous.
25. The method of any of the previous clauses, wherein the feature is a structure capable of generating wide angle diffraction, and wherein the scanning is performed: perpendicular to the feature; along one side of the feature, wherein a spot size of the radiation is configured to cover the one side of the feature; or along both sides of the feature, wherein the spot size of the radiation is configured to cover both sides of the feature at the same time.
26. The method of any of the previous clauses, wherein the feature comprises a line, an edge, or a fine-pitched series of lines and/or edges, and wherein the feature has a length spanning a region of measurement interest.
27. The method of any of the previous clauses, wherein a fine-pitch has a pitch dimension of less than 1 micrometer.
28. The method of any of the previous clauses, wherein the irradiating and the detecting comprises scanning, and wherein the scanning is performed faster and is configured to generate more information than in typical systems for generating metrology signals because the scanning is performed on the feature and continuously samples deformation across a large region of a field or wafer rather than a series of discrete alignment marks, and because the feature is configured to span an interior of device dies without causing processing and packaging issues.
29. The method of any of the previous clauses, wherein the irradiating and the detecting comprises scanning, and wherein the scanning is performed faster and is configured to generate more information than in typical systems for generating metrology signals because the scanning is performed on the feature in the patterned substrate instead of on the dedicated alignment structure.
30. The method of any of the previous clauses, wherein the irradiating and the detecting comprises scanning, and wherein the metrology signal is calibrated based on a scan of the feature isolated from other surrounding structures.
31. The method of any of the previous clauses, wherein the irradiating and the detecting comprises scanning, wherein the metrology signal is calibrated based on a perpendicular or parallel line scan.
32. The method of any of the previous clauses, wherein the metrology signal comprises a signal from a parallel flank scan, a signal from a flank scan comprising diffraction oriented perpendicular from a scan direction, the signal from the parallel flank scan comprising a difference between a signal from a first scan of the feature and a second parallel scan of the feature.
33. The method of any of the previous clauses, wherein the metrology signal comprises a signal from two parallel flank scans on two corresponding features from two different regions, the signal from the two parallel flank scans comprising a difference between a first signal from a first parallel flank scan from a first region and a second signal from a second parallel flank scan from a second region, wherein a given signal from a given parallel flank scan comprises a difference between a signal from a first scan of the feature and a second parallel scan of the feature, where different regions comprise different dies on one substrate or the same dies between different substrates.
34. The method of any of the previous clauses, wherein the irradiating and detecting comprise scanning, and wherein the scanning is performed at a predefined scan speed for a given sampling rate, the predefined scan speed and/or given sampling rate determined based on a size of the feature.
35. The method of any of the previous clauses, wherein the predefined scan speed and/or given sampling rate are adjustable based on the size of the feature.
36. The method of any of the previous clauses, wherein sizes of features that can be scanned are determined based on a ratio of the predefined scan speed to the given sampling rate.
37. The method of any of the previous clauses, wherein the feature comprises a line and/or an edge, the dedicated alignment structure comprises a diffraction grating, and the line and/or edge feature forms a portion of a design layout, separate from the diffraction grating.
38. The method of any of the previous clauses, wherein the metrology signal is an alignment signal or an overlay signal.
39. The method of any of the previous clauses, further comprising determining, based on the metrology signal, an alignment inspection location of the feature.
40. The method of any of the previous clauses, wherein the feature is included in a layer of the substrate in a semiconductor device structure, and the method further comprises adjusting a semiconductor device manufacturing process based on the metrology signal.
41. A non-transitory computer readable medium having instructions thereon, the instructions when executed by a computer, causing operations comprising: irradiating a feature in a patterned substrate with radiation, the feature being different than a dedicated alignment structure; detecting reflected radiation from the feature; and generating a metrology signal based on the detected reflected radiation from the feature, the metrology signal comprising measurement information pertaining to the feature.
42. The medium of clause 41, wherein the feature comprises one or more structures in the patterned substrate capable of providing a diffraction signal.
43. The medium of any of the previous clauses, wherein the feature is different than the dedicated alignment structure and other structures that lie near the feature and within an illumination spot.
44. The medium of any of the previous clauses, wherein the irradiating and the detecting comprises scanning, and wherein the scanning is continuous.
45. The medium of any of the previous clauses, wherein the feature is a structure capable of generating wide angle diffraction, and wherein the scanning is performed: perpendicular to the feature; along one side of the feature, wherein a spot size of the radiation is configured to cover the one side of the feature; or along both sides of the feature, wherein the spot size of the radiation is configured to cover both sides of the feature at the same time.
46. The medium of any of the previous clauses, wherein the feature comprises a line, an edge, or a fine-pitched series of lines and/or edges, and wherein the feature has a length spanning a region of measurement interest.
47. The medium of any of the previous clauses, wherein a fine-pitch has a pitch dimension of less than 1 micrometer.
48. The medium of any of the previous clauses, wherein the irradiating and the detecting comprises scanning, and wherein the scanning is performed faster and is configured to generate more information than in typical systems for generating metrology signals because the scanning is performed on the feature and continuously samples deformation across a large region of a field or wafer rather than a series of discrete alignment marks, and because the feature is configured to span an interior of device dies without causing processing and packaging issues.
49. The medium of any of the previous clauses, wherein the irradiating and the detecting comprises scanning, and wherein the scanning is performed faster and is configured to generate more information than in typical systems for generating metrology signals because the scanning is performed on the feature in the patterned substrate instead of on the dedicated alignment structure.
50. The medium of any of the previous clauses, wherein the irradiating and the detecting comprises scanning, and wherein the metrology signal is calibrated based on a scan of the feature isolated from other surrounding structures.
51. The medium of any of the previous clauses, wherein the irradiating and the detecting comprises scanning, wherein the metrology signal is calibrated based on a perpendicular or parallel line scan.
52. The medium of any of the previous clauses, wherein the metrology signal comprises a signal from a parallel flank scan, a signal from a flank scan comprising diffraction oriented perpendicular from a scan direction, the signal from the parallel flank scan comprising a difference between a signal from a first scan of the feature and a second parallel scan of the feature.
53. The medium of any of the previous clauses, wherein the metrology signal comprises a signal from two parallel flank scans on two corresponding features from two different regions, the signal from the two parallel flank scans comprising a difference between a first signal from a first parallel flank scan from a first region and a second signal from a second parallel flank scan from a second region, wherein a given signal from a given parallel flank scan comprises a difference between a signal from a first scan of the feature and a second parallel scan of the feature, where different regions comprise different dies on one substrate or the same dies between different substrates.
54. The medium of any of the previous clauses, wherein the irradiating and detecting comprise scanning, and wherein the scanning is performed at a predefined scan speed for a given sampling rate, the predefined scan speed and/or given sampling rate determined based on a size of the feature.
55. The medium of any of the previous clauses, wherein the predefined scan speed and/or given sampling rate are adjustable based on the size of the feature.
56. The medium of any of the previous clauses, wherein sizes of features that can be scanned are determined based on a ratio of the predefined scan speed to the given sampling rate.
57. The medium of any of the previous clauses, wherein the feature comprises a line and/or an edge, the dedicated alignment structure comprises a diffraction grating, and the line and/or edge feature forms a portion of a design layout, separate from the diffraction grating.
58. The medium of any of the previous clauses, wherein the metrology signal is an alignment signal or an overlay signal.
59. The medium of any of the previous clauses, the operations further comprising determining, based on the metrology signal, an alignment inspection location of the feature.
60. The medium of any of the previous clauses, wherein the feature is included in a layer of the substrate in a semiconductor device structure, and the method further comprises adjusting a semiconductor device manufacturing process based on the metrology signal.
61. A method for generating an alignment signal for alignment of features in a layer of a substrate as part of a semiconductor manufacturing process, the method configured to be performed faster and generate more information than typical methods for generating alignment signals because the method is performed on existing structures in a patterned semiconductor wafer instead of on dedicated alignment structures, the method comprising: continuously scanning a line and/or edge feature of the patterned semiconductor wafer, the line and/or edge feature being different than a dedicated alignment mark typically included in the patterned semiconductor wafer; wherein the scanning comprises: continuously irradiating the line and/or edge feature with radiation; and continuously detecting reflected radiation from the line and/or edge feature; and wherein the scanning is performed: perpendicular to the line and/or edge feature; along one side of the line and/or edge feature; or along both sides of the line and/or edge feature; and generating the alignment signal based on the detected reflected radiation from the line and/or edge feature; the alignment signal configured to be used to adjust the semiconductor manufacturing process.
62. The method of any of the previous clauses, wherein the alignment signal is calibrated based on a scan of the feature isolated from surrounding structure.
63. The method of any of the previous clauses, wherein the alignment signal comprises a signal from a parallel flank scan, a signal from a flank scan comprising diffraction oriented perpendicular from a scan direction, the signal from the parallel flank scan comprising a difference between a signal from a first scan of the line and/or edge feature and a second parallel scan of the line and/or edge feature.
64. The method of any of the previous clauses, wherein the alignment signal comprises a signal from two parallel flank scans on two corresponding line and/or edge features from two different regions, the signal from the two parallel flank scans comprising a difference between a first signal from a first parallel flank scan from a first region and a second signal from a second parallel flank scan from a second region, wherein a given signal from a given parallel flank scan comprises a difference between a signal from a first scan of the line and/or edge feature and a second parallel scan of the line and/or edge feature, wherein different regions comprise different dies on one substrate or the same dies between different substrates.
65. The method of any of the previous clauses, wherein the scanning is performed at a predefined scan speed for a given sampling rate, the predefined scan speed and/or given sampling rate determined based on a size of the line and/or edge feature.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments.

The descriptions above are intended to be illustrative, not limiting. Thus, it will be apparent to one skilled in the art that modifications may be made as described without departing from the scope of the claims set out below.

1. A system for generating a metrology signal, the system comprising:
a sensor configured to detect reflected radiation from a feature in a patterned substrate irradiated with radiation, the feature being different than a dedicated alignment structure; and
one or more processors configured to generate the metrology signal based on the detected reflected radiation from the feature, the metrology signal comprising measurement information pertaining to the feature.

2. The system of claim 1, wherein the feature comprises one or more structures in the patterned substrate capable of providing a diffraction signal.

3. The system of claim 1, wherein the feature is different than the dedicated alignment structure and other structures that lie near the feature and within an illumination spot.

4. The system of claim 1, wherein the irradiation and detection comprises a continuous scanning of the feature.

5. The system of claim 4, wherein the feature is a structure capable of generating wide angle diffraction, and wherein the scanning is:
perpendicular to the feature;
along one side of the feature, wherein a spot size of the radiation is configured to cover the one side of the feature; or
along both sides of the feature, wherein the spot size of the radiation is configured to cover both sides of the feature at the same time.

6. The system of claim 1, wherein the feature comprises a line, an edge, or a fine-pitched series of lines and/or edges, and wherein the feature has a length spanning a region of measurement interest.

7. The system of claim 6, wherein the feature comprises the fine-pitched series of lines and/or edges and the fine-pitch has a pitch dimension of less than 1 micrometer.

8. The system of claim 1, wherein the irradiation and detection comprises a scanning, and wherein the scanning is performed faster and is configured to generate more information than in typical systems for generating metrology signals because the scanning is performed on the feature and continuously samples deformation across a large region of a field or wafer rather than a series of discrete alignment marks, and because the feature is configured to span an interior of device dies without causing processing and packaging issues.

9. The system of claim 1, wherein the irradiation and detection comprises a scanning, and wherein the scanning is performed faster and is configured to generate more information than in typical systems for generating metrology signals because the scanning is performed on the feature in the patterned substrate instead of on the dedicated alignment structure.

10. The system of claim 1, wherein the irradiation and detection comprises a scanning, and wherein the metrology signal is calibrated based on a scan of the feature isolated from other surrounding structures.

11. The system of claim 1, wherein the irradiation and detection comprises a scanning, and wherein the metrology signal is calibrated based on a perpendicular or parallel line scan.

12. The system of claim 1, wherein the metrology signal comprises a signal from a parallel flank scan, a signal from a flank scan comprising diffraction oriented perpendicular from a scan direction, the signal from the parallel flank scan comprising a difference between a signal from a first scan of the feature and a second parallel scan of the feature.

13. The system of claim 1, wherein the metrology signal comprises a signal from two parallel flank scans on two corresponding features from two different regions, the signal from the two parallel flank scans comprising a difference between a first signal from a first parallel flank scan from a first region and a second signal from a second parallel flank scan from a second region, and wherein a given signal from a given parallel flank scan comprises a difference between a signal from a first scan of the feature and a second parallel scan of the feature, where different regions comprise different dies on one substrate or the same dies between different substrates.

14. The system of claim 1, wherein the irradiation and detection comprises a scanning, and wherein the scanning is performed at a predefined scan speed for a given sampling rate, the predefined scan speed and/or given sampling rate determined based on a size of the feature.

15. The system of claim 14, wherein the predefined scan speed and/or given sampling rate are adjustable based on the size of the feature.

16. The system of claim 14, wherein the size of feature that can be scanned is determined based on a ratio of the predefined scan speed to the given sampling rate.

17. The system of claim 1, wherein the feature comprises a line and/or an edge, the dedicated alignment structure comprises a diffraction grating, and the line and/or edge feature forms a portion of a design layout, separate from the diffraction grating.

18. The system of claim 1, wherein the metrology signal is an alignment signal or an overlay signal.

19. The system of claim 1, wherein the one or more processors are further configured to determine, based on the metrology signal, an alignment inspection location of the feature.

20. The system of claim 1, wherein the feature is included in a layer of the substrate in a semiconductor device structure, and wherein the one or more processors are further configured to adjust a semiconductor device manufacturing process based on the metrology signal.
